(19) United States
(12) Patent Application Publication
(10) Pub. No.: US 2026/0084246 A1
(43) Pub. Date: Mar. 26, 2026

(54) LASER PROCESSING APPARATUS AND METHOD OF MANUFACTURING DISPLAY DEVICE USING THE SAME

(71) Applicant: Samsung Display Co., LTD., Yongin-si (KR)

(72) Inventor: SUKBONG LEE, Yongin-si (KR)

(21) Appl. No.: 18/896,657

(22) Filed: Sep. 25, 2024

(51) Int. Cl. B23K 26/38; B23K 26/064; H10K 71/00

(52) U.S. Cl. CPC B23K 26/38; B23K 26/064; H10K 71/00

(57) ABSTRACT

A laser processing apparatus includes: a stage on which a display substrate having a display area and a carrier substrate are loaded; a light source part that irradiates a laser to the carrier substrate; and a refractive optical system that refracts the laser. The laser includes a first laser that passes through the refractive optical system and a second laser that bypasses the refractive optical system. The first laser and the second laser are incident at a boundary between the display substrate and the carrier substrate, and the second laser is incident at the display area of the display substrate.

### BACKGROUND

### 1. Field

The present disclosure relates generally to a laser processing apparatus. More particularly, the present disclosure relates to a laser processing apparatus and a method of manufacturing a display device using the same.

### 2. Description of the Related Art

With the advancement of information technology, display devices have become increasingly important as the interface between users and information. For example, the use of display devices such as a liquid crystal display (LCD) device, an organic light emitting display (OLED) device, a plasma display panel (PDP) device, and a quantum dot display device is increasing.

The display device may include a display substrate having excellent flexibility. When the display device includes the display device having excellent flexibility, the display substrate may be supported during a process of manufacturing the display device. Therefore, after forming the display substrate on a carrier substrate, the carrier substrate may be removed after the process of manufacturing the display device. The carrier substrate may be removed by various methods, among which a laser lift-off method using a laser is being studied.

### SUMMARY

Embodiments provide a laser processing apparatus with reduced peeling defects.

Embodiments provide a method of manufacturing a display device using the laser processing apparatus.

A laser processing apparatus according to an embodiment of the present disclosure includes: a stage on which a display substrate having a display area and a carrier substrate are loaded; a light source part that irradiates a laser to the carrier substrate; and a refractive optical system that refracts the laser. The laser includes a first laser that passes through the refractive optical system and a second laser that bypasses the refractive optical system. The first laser and the second laser are incident at a boundary between the display substrate and the carrier substrate, and the second laser is incident at the display area of the display substrate.

In an embodiment, a first intensity of the laser incident at the display area of the display substrate may be different from a second intensity of the laser incident at the boundary.

In an embodiment, the second intensity may be greater than the first intensity.

In an embodiment, the laser processing apparatus may further include a laser filter that passes a portion of the first laser. The second laser and the portion of the first laser are incident at the boundary.

In an embodiment, the display substrate may include a first side extending in a first direction and a second side contacting the first side and extending in a second direction intersecting the first direction. A length of the second side may be greater than a length of the first side. The boundary may correspond to the second side.

In an embodiment, the laser processing apparatus may further include a transport part that moves the light source part. The light source part may move in the second direction.

In an embodiment, the laser may have a linear shape.

In an embodiment, the laser may be an excimer laser.

A method of manufacturing a display device according to an embodiment of the present disclosure includes: forming a display substrate having a display area on a first surface of a carrier substrate; forming a light emitting element in the display area on the display substrate; and peeling off the display substrate and the carrier substrate by irradiating a laser to the carrier substrate. A first intensity of the laser incident at the display area of the display substrate is different from a second intensity of the laser incident at a boundary between the display substrate and the carrier substrate.

In an embodiment, the second intensity may be greater than the first intensity.

In an embodiment, the irradiating the laser may include passing the laser through a refractive optical system. The laser may include a first laser that passes through the refractive optical system and a second laser that bypasses the refractive optical system.

In an embodiment, the first laser may be incident at the boundary.

In an embodiment, the first laser and the second laser may be incident at the boundary, and the second laser may be incident at the display area of the display substrate.

In an embodiment, the irradiating the laser may further include passing the first laser through a laser filter. A portion of the first laser that passes through the laser filter may be incident at the boundary.

In an embodiment, the second laser and the portion of the first laser may be incident at the boundary, and the second laser may be incident at the display area of the display substrate.

In an embodiment, the display substrate may include a first side extending in a first direction and a second side contacting the first side and extending in a second direction intersecting the first direction. A length of the second side may be greater than a length of the first side. The boundary may correspond to the second side.

In an embodiment, the laser may have a linear shape and may scan along the second direction in the irradiating the laser.

In an embodiment, the laser may be irradiated to a second surface opposite to the first surface of the carrier substrate.

In an embodiment, the display substrate may include a first organic layer and a second organic layer disposed on the first organic layer. At least a portion of the second organic layer may protrude further than an edge of the first organic layer in a plan view.

In an embodiment, the display substrate may include a colorless polyimide.

A laser processing apparatus according to an embodiment of the present disclosure may include a light source part that irradiates a laser and a refractive optical system that refracts the laser. The laser may include a first laser that passes through the refractive optical system and a second laser that bypasses the refractive optical system.

As the refractive optical system refracts the first laser, the first laser may be incident at a boundary between a display substrate and a carrier substrate. In addition, the second laser that bypasses the refractive optical system may be incident at the display substrate.

That is, the first laser and the second laser may be incident at the boundary. In other words, a laser having a relatively strong intensity in which the first laser and the second laser overlap may be incident at the boundary. Accordingly, the display substrate and the carrier substrate may be effectively peeled off at the boundary.

In addition, a laser having a relatively small intensity by the second laser may be incident at a display area of the display substrate. Accordingly, a defect of an encapsulation layer included in a display device being peeled off in a process of manufacturing the display device may be effectively reduced.

### BRIEF DESCRIPTION OF THE DRAWINGS

Illustrative, non-limiting embodiments will be more clearly understood from the following detailed description in conjunction with the accompanying drawings.

FIG. 1 is a side view illustrating a laser processing apparatus according to an embodiment of the present disclosure.

FIG. 2 is a plan view illustrating the laser processing apparatus of FIG. 1.

FIG. 3 is a side view illustrating the laser processing apparatus of FIG. 1.

FIG. 4 is a view for describing an intensity of a laser incident at a display substrate of FIG. 1.

FIG. 5 is a side view illustrating a laser processing apparatus according to an embodiment of the present disclosure.

FIG. 6 is a flowchart of a method of manufacturing a display device according to an embodiment of the present disclosure.

FIGS. 7, 8, 9, 10, 11, 12, 13, 14, 15, 16, and 17 are views illustrating the method of manufacturing the display device of FIG. 6.

### DETAILED DESCRIPTION OF THE EMBODIMENTS

Hereinafter, embodiments of the present disclosure will be described in detail with reference to the accompanying drawings. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts. The same reference numerals are used for identical components in the drawings, and redundant descriptions of these components may be omitted.

In this specification, a plane may be defined by a first direction DR1 and a second direction DR2 intersecting the first direction DR1. For example, the first direction DR1 and the second direction DR2 may be perpendicular to each other. A direction normal to the plane may be a third direction DR3. In other words, the third direction DR3 may be perpendicular to each of the first direction DR1 and the second direction DR2.

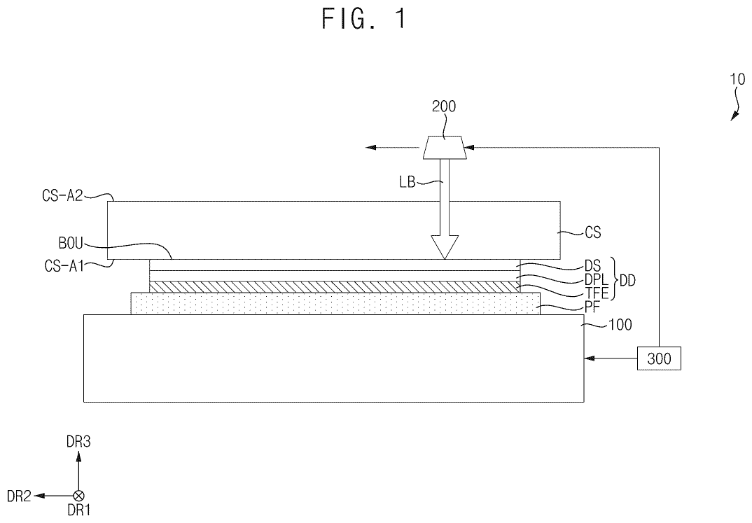

FIG. 1 is a side view illustrating a laser processing apparatus according to an embodiment of the present disclosure. For example, FIG. 1 is a view illustrating a laser processing apparatus 10 in the first direction DR1.

Referring to FIG. 1, the laser processing apparatus 10 according to an embodiment of the present disclosure may include a stage 100, a light source part 200, and a transport part 300.

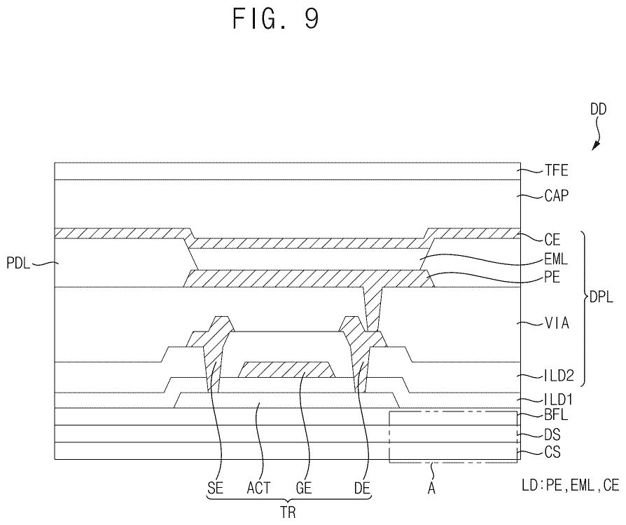

The stage 100 may include a flat upper surface. A carrier substrate CS and a display substrate DS may be loaded on the stage 100. Specifically, a display device DD formed on a first surface CS-A1 of the carrier substrate CS may be positioned on the upper surface of the stage 100. In addition, a protective film PF formed on the display device DD may be positioned on the upper surface of the stage 100. In other words, the carrier substrate CS may face the light source part 200 and the protective film may face the stage 100. In this case, the display device DD may include the display substrate DS, a display layer DPL, and an encapsulation layer TFE. A detailed description thereof is described herein with reference to FIG. 9.

The light source part 200 may be positioned on the stage 100. Specifically, the light source part 200 may be positioned on the carrier substrate CS. The light source part 200 may include a laser light source and a beam shaping optical system. The laser light source may irradiate a laser LB. Specifically, the laser light source may irradiate the laser LB on a second surface CS-A2 opposite to the first surface CS-A1 of the carrier substrate CS. The beam shaping optical system may include a homogenizer, a condenser, and the like. The homogenizer may homogenize the laser LB, and the condenser may focus the laser LB. However, the present disclosure is not limited thereto, and the beam shaping optical system may include various optical elements.

In an embodiment, the beam shaping optical system may deform the laser LB to have a linear shape. A linear laser LB may have a beam shape including a short-direction and a long-direction, and may have a uniform energy density.

In an embodiment, the laser LB may be an excimer laser. For example, the excimer laser may be an XeCl excimer laser that emits ultraviolet light of about 308 nanometers. However, the present disclosure is not limited thereto, and the laser LB may be various types of lasers having a wavelength of about 300 nanometers to about 350 nanometers.

The light source part 200 may be moved in the second direction DR2 by the transport part 300. Accordingly, the laser LB may scan a boundary surface BOU between the display substrate DS and the carrier substrate CS. However, the present disclosure is not limited thereto, and the transport portion 300 may move the stage 100 in a opposite direction to the second direction DR2.

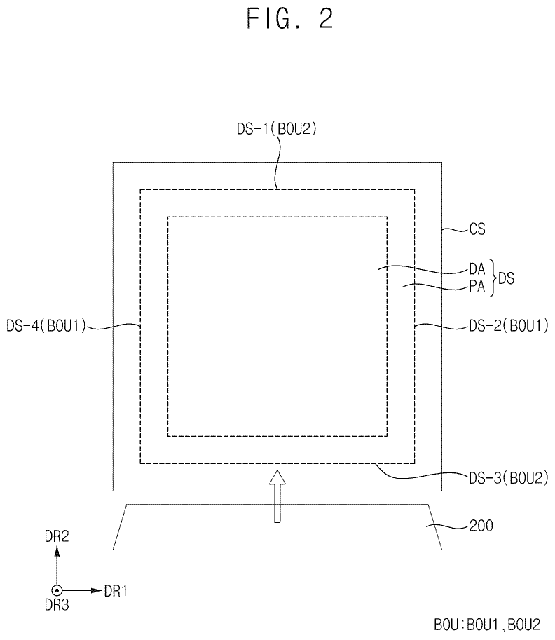

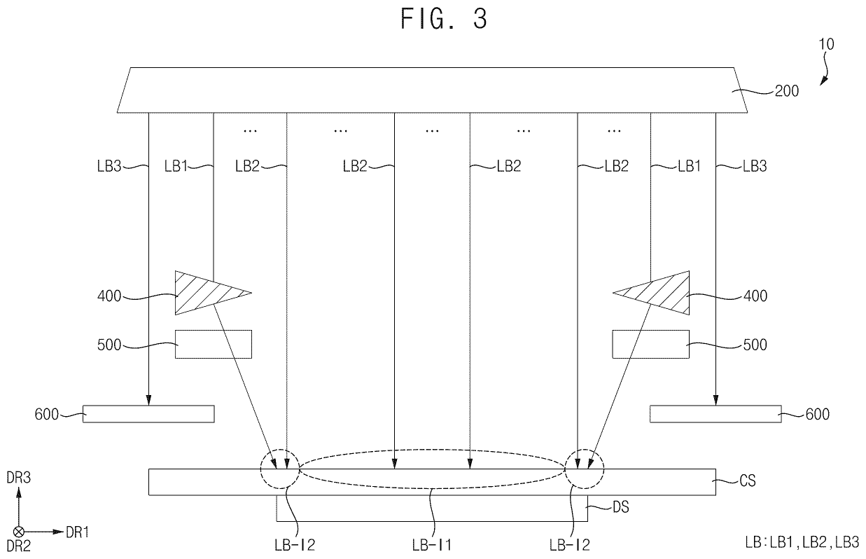

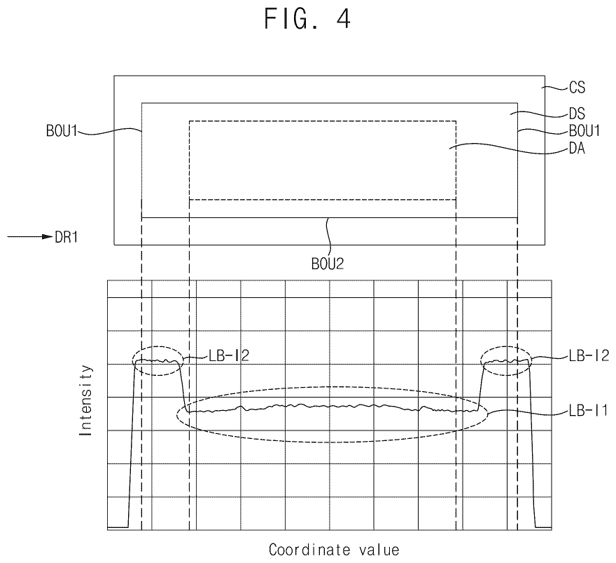

FIG. 2 is a plan view illustrating the laser processing apparatus of FIG. 1. For example, FIG. 2 is a view illustrating the laser processing apparatus 10 in the third direction DR3. FIG. 3 is a side view illustrating the laser processing apparatus of FIG. 1. For example, FIG. 3 is a view illustrating the laser processing apparatus 10 in the second direction DR2. FIG. 4 is a view for describing an intensity of a laser incident at a display substrate of FIG. 1.

Referring to FIGS. 2, 3, and 4, the laser processing apparatus 10 may include the light source part 200, a refractive optical system 400, a laser filter 500, and a laser cutter 600.

The light source part 200 may irradiate the laser LB on the second surface (CS-A2, refer to FIG. 1) of the carrier substrate CS. The light source part 200 may move in the second direction DR2. Accordingly, the laser LB may scan the boundary surface BOU between the display substrate DS and the carrier substrate CS.

The display substrate DS may be positioned on the first surface (CS-A1, refer to FIG. 1) of the carrier substrate CS. The display substrate DS may have a display area DA and a peripheral area PA.

The display area DA may be defined as an area that displays an image by generating light or adjusting the transmittance of light provided from an external light source. A light emitting element (LD, refer to FIG. 9) may be disposed in the display area DA on the display substrate DS.

The peripheral area PA may be adjacent to the display area DA. For example, the peripheral area PA may surround at least a portion of the display area DA. The peripheral area PA may be defined as an area that does not display an image.

The display substrate DS may include a first side DS-1, a second side DS-2, a third side DS-3, and a fourth side DS-4. For example, the display substrate DS may have a rectangular shape. The first side DS-1 may extend in the first direction DR1. The third side DS-3 may face the first side DS-1 and may extend parallel to the first side DS-1. The second side DS-2 may contact each of the first side DS-1 and the third side DS-3 and may extend in the second direction DR2. The fourth side DS-4 may contact each of the first side DS-1 and the third side DS-3. The fourth side DS-4 may face the second side DS-2 and may extend parallel to the second side DS-2. In other words, each of the second side DS-2 and the fourth side DS-4 may be disposed between the first side DS-1 and the third side DS-3. The first to fourth sides DS-1, DS-2, DS-3, DS-4 may define an edge of the display substrate DS.

The carrier substrate CS may overlap an entirety of the display substrate DS in a plan view. An area where the display substrate DS and the carrier substrate CS overlap in a plan view may be substantially the same as the boundary surface BOU between the display substrate DS and the carrier substrate CS.

The boundary surface BOU between the display substrate DS and the carrier substrate CS may include a first boundary BOU1 and a second boundary BOU2. The first boundary BOU1 may extend in the second direction DR2. As the second side DS-2 and the fourth side DS-4 define the edge of the display substrate DS, the first boundary BOU1 may correspond to the second side DS-2 and the fourth side DS-4. The second boundary BOU2 may extend in the first direction DR1. As the first side DS-1 and the third side DS-3 define the edge of the display substrate DS, the second boundary BOU2 may correspond to the first side DS-1 and the third side DS-3.

In an embodiment, a length of the second side DS-2 may be greater than a length of the first side DS-1, and a length of the fourth side DS-4 may be greater than a length of the third side DS-3. In this case, the first boundary BOU1 may be defined as a long-direction boundary and the second boundary BOU2 may be defined as a short-direction boundary.

As illustrated in FIG. 3, the light source part 200 may irradiate the laser LB towards the carrier substrate CS. In this case, the laser LB may include a first laser LB1, a second laser LB2, and a third laser LB3. As the beam shaping optical system homogenizes the laser LB, each of the first laser LB1, the second laser LB2, and the third laser LB3 may have the same energy density as each other.

The first laser LB1 may be defined as the laser LB that passes through the refractive optical system 400 and is incident at the first boundary BOU1. The first laser LB1 may travel parallel to the third direction DR3 and change its travel direction after passing through the refractive optical system 400. After the travel direction changes, the first laser LB1 may be incident at the first boundary BOU1.

The refractive optical system 400 may refract the first laser LB1. In other words, the travel direction of the first laser LB1 before passing through the refractive optical system 400 and the travel direction of the first laser LB1 after passing through the refractive optical system 400 may be different from each other. The refractive optical system 400 may include various optical elements.

In an embodiment, the first laser LB1 may pass through the laser filter 500. Specifically, after passing through the refractive optical system 400, the first laser LB1 may further pass through the laser filter 500. In this case, a portion of the first laser LB1 that passes through the laser filter 500 may be incident at the first boundary BOU1.

The laser filter 500 may control an amount of first laser LB1 incident at the first boundary BOU1. That is, the laser filter may pass a portion of the first laser LB1. In other words, an energy density of the first laser LB1 after passing through the laser filter 500 may be less than an energy density of the first laser LB1 before passing through the laser filter 500. The laser filter 500 may include various optical elements. In an embodiment, the laser filter 500 may be omitted. In this case, the first laser LB1 may pass through only the refractive optical system 400.

The second laser LB2 may be defined as the laser LB that bypasses the refractive optical system and is incident at the display substrate DS through the carrier substrate CS. That is, the second laser LB2 may not pass through the refractive optical system 400. The second laser LB2 may travel parallel to the third direction DR3. The second laser LB2 may be incident at each of the display area DA of the display substrate DS and the first boundary BOU1.

The third laser LB3 may be defined as the laser LB that meets the laser cutter 600. In other words, the third laser LB3 may travel parallel to the third direction DR3 and meet the laser cutter 600. In an embodiment, in cross-section, the laser cutter 600 may be positioned between the refractive optical system 400 and the carrier substrate CS. However, the present disclosure is not limited thereto.

The laser cutter 600 may block the third laser LB3. Accordingly, the third laser LB3 may not reach the display substrate DS and the carrier substrate CS. In addition, among the laser LB that passes through each of the refractive optical system 400 and the laser filter 500, a laser that proceeds toward an area other than the first boundary BOU1 may be blocked by the laser cutter 600.

The first laser LB1 and the second laser LB2 may be incident at the first boundary BOU1 between the display substrate DS and the carrier substrate CS. In addition, the second laser LB2 may be incident at the display area DA of the display substrate DS. That is, the first laser LB1 and the second laser LB2 may overlap at the first boundary BOU1.

FIG. 4 illustrates the correlation between a coordinate value of the first direction DR1 of the display substrate DS and an intensity of the laser. The intensity of the laser may refer to the energy density of the laser.

As illustrated in FIG. 4, the intensity of the laser incident at the display area DA of the display substrate DS may be defined as a first intensity LB-I1, and the intensity of the laser incident at the first boundary BOU1 may be defined as a second intensity LB-I2. In this case, the first intensity LB-I1 and the second intensity LB-I2 may be different from each other. Specifically, the second intensity LB-I2 may be greater than the first intensity LB-I1. In other words, the energy density of the laser incident at the first boundary BOU1 may be greater than the energy density of the laser incident at the display area DA of the display substrate DS.

The second intensity LB-I2 may be adjusted using the refractive optical system 400 and the laser filter 500. Specifically, the second intensity LB-I2 may be adjusted by changing the refractive index of the refractive optical system 400 to adjust the travel direction of the first laser LB1 after passing through the refractive optical system 400. In addition, the second intensity LB-I2 may be adjusted by control the amount of the first laser LB1 passed by the laser filter 500.

In a conventional laser processing apparatus, the display substrate DS and the carrier substrate CS may not be sufficiently peeled off due to insufficient laser intensity at an edge of the display substrate DS. When the carrier substrate CS is removed while the display substrate DS and the carrier substrate CS are not sufficiently peeled off, a defect in which the display substrate DS is wrinkled may occur.

In addition, when the laser intensity is relatively increased to sufficiently peel off the display substrate DS and the carrier substrate CS at the edge of the display substrate DS, a problem of peeling off the encapsulation layer (TFE, refer to FIG. 1) disposed on the display substrate DS may occur. Specifically, when the laser intensity is relatively strong, an adhesive force between an upper electrode (CE, refer to FIG. 9) and a capping layer (CAP, refer to FIG. 9) may be weakened by a shockwave generated at the boundary surface BOU between the display substrate DS and the carrier substrate CS. Accordingly, during a process of removing the protective film (PF, refer to FIG. 1), a problem of peeling off the encapsulation and the capping layer may occur.

The laser processing apparatus 10 according to an embodiment of the present disclosure may include the refractive optical system 400. As the refractive optical system 400 refracts the first laser LB1, the first laser LB1 may be incident at the first boundary BOU1 between the display substrate DS and the carrier substrate CS. Accordingly, the first laser LB1 and the second laser LB2 may be incident at the first boundary BOU1. That is, a laser having the second intensity LB-I2 in which the first laser LB1 and the second laser LB2 overlap may be incident at the first boundary BOU1. In addition, a laser having the first intensity LB-I1 by the second laser LB2 may be incident at the display area DA of the display substrate DS. The second intensity LB-I2 may be greater than the first intensity LB-I1.

In other words, a laser having the relatively strong second intensity LB-I2 may be incident at the first boundary BOU1 between the display substrate DS and the carrier substrate CS. Accordingly, the display substrate DS and the carrier substrate CS may be effectively peeled off at the first boundary BOU1.

In addition, to incident a laser having a relatively strong intensity at the second boundary BOU2 between the display substrate DS and the carrier substrate CS, a movement speed of the light source part 200 may be adjusted. That is, the movement speed of the light source part 200 may be relatively reduced at a portion overlapping the second boundary BOU2 in a plan view. As a result, as the laser LB overlaps relatively more at the portion overlapping the second boundary BOU2 in a plan view, a laser having a relatively strong intensity may be incident at the second boundary BOU2. Accordingly, the display substrate DS and the carrier substrate CS may be effectively peeled off at the second boundary BOU2.

In summary, the display substrate DS and the carrier substrate CS may be effectively peeled off at the edge (e.g., the first boundary BOU1 and the second boundary BOU2) of the display substrate DS.

In addition, a laser having the relatively small first intensity LB-I1 may be incident at the display area DA of the display substrate DS. That is, a defect of the encapsulation layer being peeled off together in the process of removing the protective film may be effectively reduced.

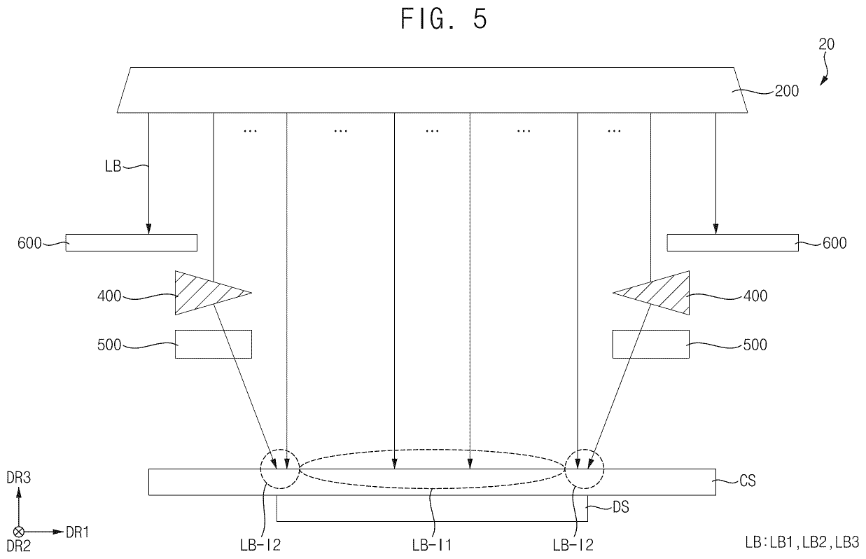

FIG. 5 is a side view illustrating a laser processing apparatus according to an embodiment of the present disclosure. For example, FIG. 5 is a view illustrating a laser processing apparatus 20 in the second direction DR2.

Referring to FIG. 5, the laser processing apparatus 20 according to an embodiment of the present disclosure may include a light source part 200, a refractive optical system 400, a laser filter 500, and a laser cutter 600.

The laser processing apparatus 20 may be substantially the same as the laser processing apparatus 10 described above reference to FIG. 3, except for a positioned relationship between the laser cutter 600 and the refractive optical system 400. Hereinafter, redundant descriptions of the laser processing apparatus 10 described above reference to FIG. 3 may be omitted or may be summarized.

In an embodiment, in cross-section, the laser cutter 600 may be positioned between the light source part 200 and the refractive optical system 400. In this case, a portion of the laser LB may be blocked by the laser cutter 600 before passing through the refractive optical system 400. The laser LB that passes through each of the refractive optical system 400 and the laser filter 500 may not be blocked by the laser cutter 600.

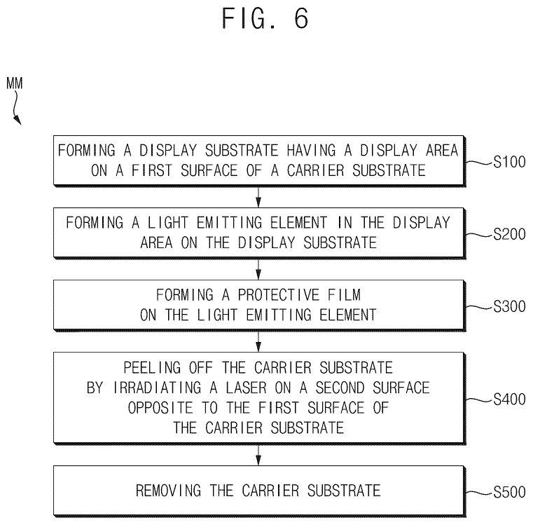

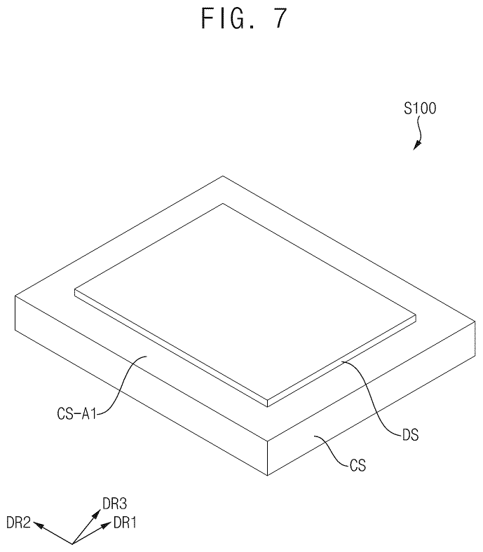

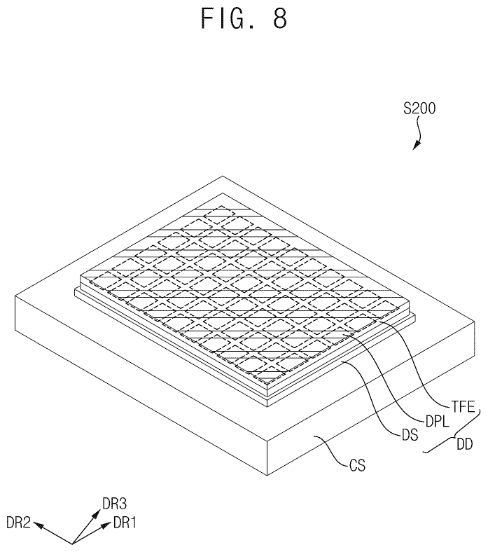

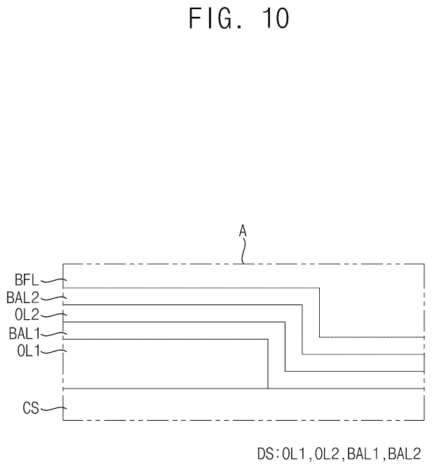

FIG. 6 is a flowchart of a method of manufacturing a display device according to an embodiment of the present disclosure. FIGS. 7, 8, 9, 10, 11, 12, 13, 14, 15, 16, and 17 are views illustrating the method of manufacturing the display device of FIG. 6. For example, FIG. 9 is a cross-sectional view illustrating a display device DD of FIG. 8, and FIG. 10 is an enlarged cross-sectional view of area A of FIG. 9.

Referring to FIGS. 1 and 6, a method MM of manufacturing a display device according to an embodiment of the present disclosure may include forming the display substrate DS having the display area DA on the first surface CS-A1 of the carrier substrate CS (S100), forming a light emitting element in the display area DA on the display substrate DS (S200), forming the protective film PF on the light emitting element (S300), peeling off the carrier substrate CS by irradiating the laser LB on the second surface CS-A2 opposite to the first surface CS-A1 of the carrier substrate CS (S400), and removing the carrier substrate CS (S500).

Referring to FIG. 7, the display substrate DS having the display area may be formed on the first surface CS-A1 of the carrier substrate CS (S100).

The carrier substrate CS may include a rigid substrate to serve as a support during the manufacturing process of the display device. In addition, the carrier substrate CS may include a transparent material so that a laser may be transmitted through the carrier substrate CS in a subsequent peeling process. For example, the carrier substrate CS may include a quartz substrate, a synthetic quartz substrate, a fluorine-doped quartz substrate, a soda-lime glass substrate, a non-alkali glass substrate, or the like. These may be used alone or in combination with each other.

The display substrate DS may be formed on the first surface CS-A1 of the carrier substrate CS. The display substrate DS may include a transparent material or an opaque material. The display substrate DS may include a quartz substrate, a synthetic quartz substrate, a fluorine-doped quartz substrate, a soda-lime glass substrate, a non-alkali glass substrate, or the like. These may be used alone or in combination with each other.

In an embodiment, the display substrate DS may include a flexible substrate. The flexible substrate may be a polyimide substrate. In this case, the polyimide substrate may include a first organic layer, a first barrier layer, a second organic layer, a second barrier layer, etc. A detailed description thereof is described herein with reference to FIG. 10.

In an embodiment, the display substrate DS may include a colorless polyimide (“CPI”). For example, the display substrate DS may include a colorless polyimide having a fluorocarbon group (—CF3).

Referring to FIGS. 8, 9, and 10, a light emitting element LD may be formed in the display area on the display substrate DS (S200). Specifically, each of the display layer DPL including the light emitting element and the encapsulation layer TFE disposed on the display layer DPL may be formed in the display area on the display substrate DS. Accordingly, the display device DD including the display substrate DS, the display layer DPL, and the encapsulation layer TFE may be formed.

As illustrated in FIG. 9, the display device DD may include the display substrate DS, a buffer layer BFL, the display layer DPL, a capping layer CPL, and the encapsulation layer TFE. In this case, the display layer DPL may include a first insulating layer ILD1, a second insulating layer ILD2, a transistor TR, a via-insulating layer VIA, a light emitting element LD, and a pixel defining layer PDL.

The transistor TR may include an active layer ACT, a gate electrode GE, a source electrode SE, and a drain electrode DE. The light emitting element LD may include a lower electrode PE, a light emitting layer EML, and an upper electrode CE.

The display substrate DS may include a flexible substrate. The flexible substrate may be a polyimide substrate. In this case, as illustrated in FIG. 10, the polyimide substrate may include a first organic layer OL1, a first barrier layer BAL1, a second organic layer OL2, and a second barrier layer BAL2.

An apparatus for forming the first organic layer OL1 and an apparatus for forming the second organic layer OL2 may be different from each other. In this case, an area where the first organic layer OL1 is formed may be different from an area where the second organic layer OL2 is formed. In an embodiment, the second organic layer OL2 may overlap an entirety of the first organic layer OL1 in a plan view, and at least a portion of the second organic layer OL2 may protrude further than an edge of the first organic layer OL1 in a plan view.

In this case, the first barrier layer BAL1 may be disposed on the carrier substrate CS. Specifically, the first barrier layer BAL1 may cover the first organic layer OL1 and may contact the carrier substrate CS. The second organic layer OL2 may be disposed on the first barrier layer BAL1, and the second barrier layer BAL2 may be disposed on the second organic layer OL2.

In an embodiment, the first organic layer OL1 may overlap an entirety of the second organic layer OL2 in a plan view, and at least a portion of the first organic layer OL1 may protrude further than an edge of the second organic layer OL2 in a plan view. In this case, the first barrier layer BAL1 may be disposed on the first organic layer OL1 and may not contact the carrier substrate CS.

The buffer layer BFL may be disposed on the display substrate DS. The buffer layer BFL may prevent diffusion of metal atoms or impurities from the display substrate DS to an upper structure (e.g., the transistor TR, the light emitting element LD, etc.). In addition, the buffer layer BFL may serve to improve flatness of a surface of the display substrate DS when the surface of the display substrate DS is not uniform. For example, the buffer layer BUF may include an organic insulating material and/or an inorganic insulating material.

The active layer ACT may be formed on the buffer layer BFL. The active layer ACT may include an oxide semiconductor, a silicon semiconductor, or an organic semiconductor. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), or the like. They may be used alone or in combination with each other. The silicon semiconductor may include amorphous silicon, polycrystalline silicon, or the like. The active layer ACT may include a source area, a drain area, and a channel area positioned between the source area and the drain area.

The first insulating layer ILD1 may be formed on the buffer layer BFL and the active layer ACT. For example, the first insulating layer ILD1 may cover the active layer ACT on the buffer layer BFL and may be formed along the profile of the active layer ACT with a substantially uniform thickness. For another example, the first insulating layer ILD1 may sufficiently cover the active layer ACT and may have a substantially flat upper surface without creating a step around the active layer ACT. The first insulating layer ILD1 may include an inorganic insulating material. Examples of the inorganic insulating material that may be used as the first insulating layer ILD1 may include silicon oxide (SiOₓ), silicon nitride (SiNₓ), silicon oxynitride (SiOₓN_{y}), etc. These may be used alone or in combination with each other.

The gate electrode GE may be formed on the first insulating layer ILD1. The gate electrode GE may overlap the active layer ACT in a plan view. The gate electrode GE may include a conductive material such as a metal, an alloy, a conductive metal nitride, a conductive metal oxide, or a transparent conductive oxide. Examples of the conductive material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in combination with each other.

The second insulating layer ILD2 may be formed on the gate electrode GE and the first insulating layer ILD1. For example, the second insulating layer ILD2 may cover the gate electrode GE on the first insulating layer ILD1 and may be formed along the profile of the gate electrode GE with substantially a uniform thickness. For another example, the second insulating layer ILD2 may sufficiently cover the gate electrode GE on the first insulating layer ILD1 and may have a substantially flat upper surface without creating a step around the gate electrode GE. The second insulating layer ILD2 may include an inorganic insulating material. Examples of the inorganic insulating material that may be used as the second insulating layer ILD2 may include silicon oxide (SiOₓ), silicon nitride (SiNₓ), silicon oxynitride (SiOₓN_{y}), etc. These may be used alone or in combination with each other.

The source electrode SE and the drain electrode DE may be formed on the second insulating layer ILD2. Each of the source electrode SE and the drain electrode DE may be electrically connected to the active layer ACT through a contact hole penetrating the first insulating layer ILD1 and the second insulating layer ILD2. Each of the source electrode SE and the drain electrode DE may include a conductive material such as a metal, an alloy, a conductive metal nitride, a conductive metal oxide, or a transparent conductive oxide. They may be used alone or in combination with each other.

Accordingly, the transistor TR including the active layer ACT, the gate electrode GE, the source electrode SE, and the drain electrode DE may be formed on the buffer layer BFL.

The via-insulating layer VIA may be formed on the second insulating layer ILD2. For example, the via-insulating layer VIA may be disposed with a relatively large thickness to sufficiently cover the source electrode SE and the drain electrode DE on the second insulating layer ILD2. The via-insulating layer VIA may include an organic insulating material or an inorganic insulating material. Examples of the organic insulating material that may be used as the via-insulating layer VIA may include a polyacryl-based resin, a polyimide-based resin, a polyamide-based resin, a siloxane-based resin, an acryl-based resin, or an epoxy-based resin. These may be used alone or in combination with each other.

The lower electrode PE may be formed on the via-insulating layer VIA. The lower electrode PE may be electrically connected to the drain electrode DE through a contact hole penetrating the via-insulating layer VIA. As a result, the lower electrode PE may be electrically connected to the transistor TR. The lower electrode PE may include a conductive material such as a metal, an alloy, a conductive metal nitride, a conductive metal oxide, or a transparent conductive oxide. They may be used alone or in combination with each other. For example, the lower electrode PE may serve as an anode electrode.

The pixel defining layer PDL may be formed on the via-insulating layer VIA. The pixel defining layer PDL may cover an edge of the lower electrode PE and may expose a portion of an upper surface of the lower electrode PE. The pixel defining layer PDL may include an organic insulating material or an inorganic insulating material. Examples of the organic insulating material that may be used as the pixel defining layer PDL may include a polyacryl-based resin, a polyimide-based resin, a polyamide-based resin, a siloxane-based resin, an acryl-based resin, an epoxy-based resin, etc. These may be used alone or in combination with each other.

The light emitting layer EML may be formed on the lower electrode PE. The light emitting layer EML may include a light emitting material. For example, the light emitting layer EML may include at least one of an organic light emitting material and a quantum dot.

The upper electrode CE may be formed on the pixel defining layer PDL and the light emitting layer EML. The upper electrode CE may include a conductive material such as a metal, an alloy, a conductive metal nitride, a conductive metal oxide, a transparent conductive oxide, etc. These may be used alone or in combination with each other. For example, the upper electrode CE may serve as a cathode electrode.

Accordingly, the light emitting element LD including the lower electrode PE, the light emitting layer EML, and the upper electrode CE may be formed. In addition, the display layer DPL including the first insulating layer ILD1, the second insulating layer ILD2, the transistor TR, the via-insulating layer VIA, the light emitting element LD, and the pixel defining layer PDL may be formed on the buffer layer BFL.

The capping layer CAP may be formed on the display layer DPL. The capping layer CAP may protect the light emitting element LD. The capping layer CAP may include an organic insulating material or an inorganic insulating material. Examples of the organic insulating material that may be used as the capping layer CAP may include a triamine derivative, an arylenediamine derivative, a 4,4′-N, N′ triamine derivative, an arylenediamine derivative, tris-8-hydroxyquinoline aluminum (“Alq3”), etc. These may be used alone or in combination with each other.

The encapsulation layer TFE may be formed on the capping layer CAP. The encapsulation layer TFE may prevent impurities, moisture, etc. from penetrating into the light emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc. These may be used alone or in combination with each other. For example, the organic encapsulation layer may include a polymer cured material such as polyacrylate.

Although the display device DD is described as an organic light emitting diode (“OLED”) display device, the present disclosure is not limited thereto. In other embodiments, the display device DD may be a liquid crystal display (“LCD”) device, a field emission display (“FED”) device, a plasma display panel (“PDP”) device, an electrophoretic image display (“EPD”) device, an inorganic light emitting diode (“ILED”) display device, or a quantum dot display device.

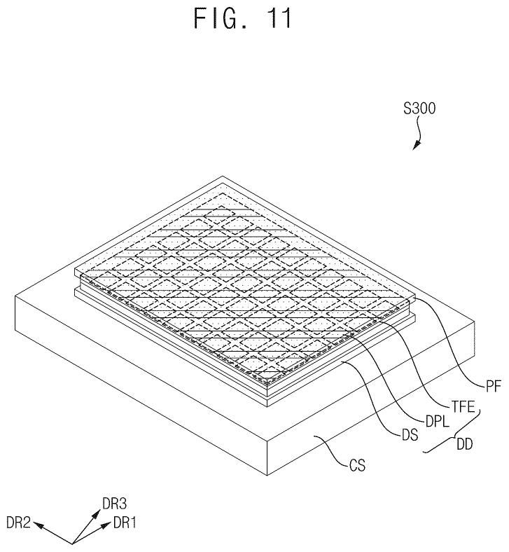

Referring to FIG. 11, the protective film PF may be formed on the light emitting element LD (S300). Specifically, the protective film PF may be formed on the encapsulation layer TFE.

The protective film PF may prevent the encapsulation layer TFE from being damaged during the subsequent process of peeling and removing the carrier substrate CS. The protective film PF may be removed after the carrier substrate CS is removed.

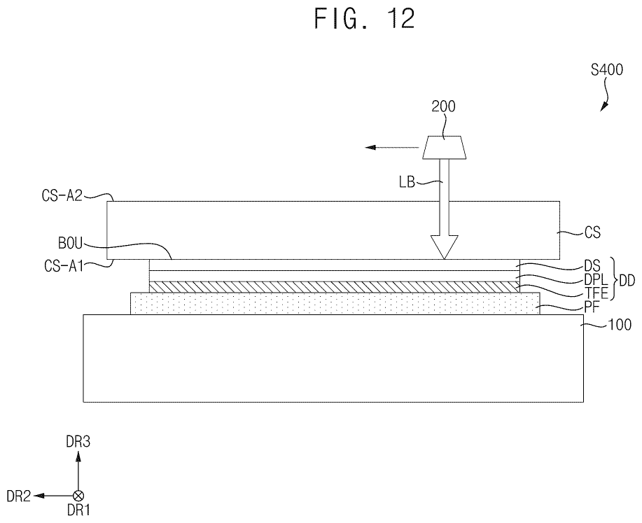

Referring to FIGS. 12, 13, 14, 15, and 16, the carrier substrate CS may be peeled off by irradiating the laser LB to the second surface CS-A2 opposite to the first surface CS-A1 of the carrier substrate CS (S400).

The light source part 200 may move in the second direction DR2 and may irradiate the laser LB on the second surface CS-A2 of the carrier substrate CS. Accordingly, the laser LB may scan the boundary surface BOU between the display substrate DS and the carrier substrate CS.

In an embodiment, the light source part 200 may move in the second direction DR2 or the opposite direction to the second direction DR2 to irradiate the laser LB in a first scan area SCA1, and after irradiating the laser LB in the first scan area SCA1, the light source part 200 may move again in the second direction DR2 or the opposite direction to the second direction DR2 to irradiate the laser LB in a second scan area SCA2. For example, the first scan area SCA1 may be a left area of the boundary surface BOU to which the light source part 200 irradiates the laser LB in a plan view, and the second scan area SCA2 may be a right area of the boundary surface BOU to which the light source part 200 irradiates the laser LB in a plan view. That is, the first scan area SCA1 may include a left side of the display area DA and a left side of the peripheral area PA, and the second scan area SCA2 may include a right side of the display area DA and a right side of the peripheral area PA. However, the present disclosure is not limited thereto.

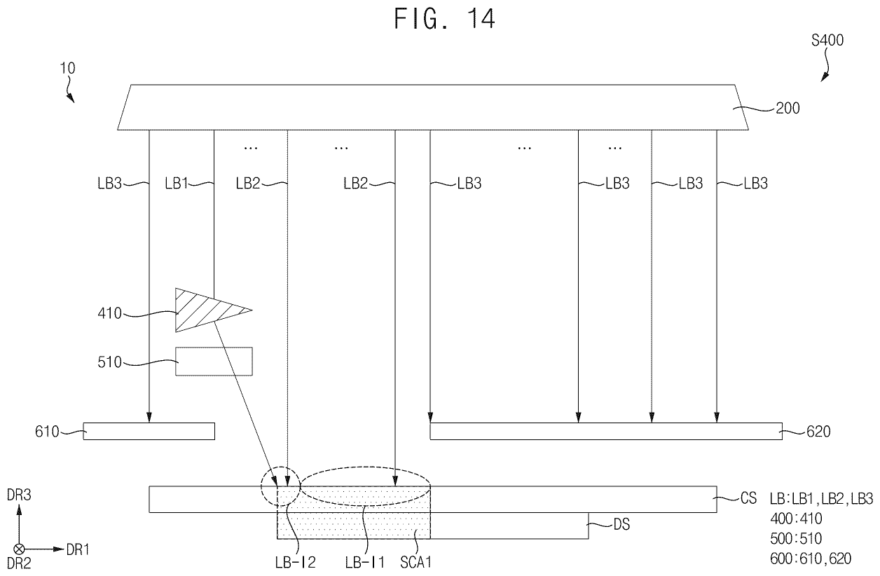

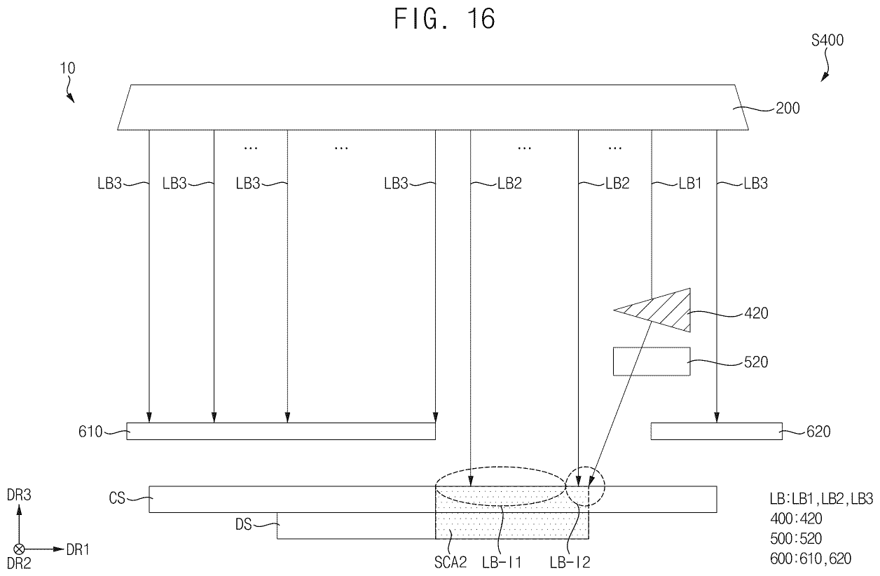

In an embodiment, as illustrated in FIGS. 14 and 16, the refractive optical system 400 may include a first refractive optical system 410 and a second refractive optical system 420 spaced apart from the first refractive optical system 410. The laser filter 500 may include a first laser filter 510 and a second laser filter 520 spaced apart from the first laser filter 510. The laser cutter 600 may include a first laser cutter 610 and a second laser cutter 620 spaced apart from the first laser cutter 610. In this case, the first refractive optical system 410, the first laser filter 510, and the first laser cutter 610 may be adjacent to the first scan area SCA1 in a plan view. The second refractive optical system 420, the second laser filter 520, and the second laser cutter 620 may be adjacent to the second scan area SCA2 in a plan view.

In an embodiment, each of the first refractive optical system 410, the second refractive optical system 420, the first laser filter 510, and the second laser filter 520 may move in the second direction DR2 or in the opposite direction to the second direction DR2. For example, the first refractive optical system 410 and the first laser filter 510 may be moved in the second direction DR2 or the opposite direction to the second direction DR2 by a first optical driver, and the second refractive optical system 420 and the second laser filter 520 may be moved in the second direction DR2 or the opposite direction to the second direction DR2 by a second optical driver. The first optical driver and the second optical driver may be driven independently of each other.

In an embodiment, each of the first laser cutter 610 and the second laser cutter 620 may move in the first direction DR1 or in an opposite direction to the first direction DR1. For example, the first laser cutter 610 may be moved in the first direction DR1 or the opposite direction to the first direction DR1 by a first cutter driver, and the second laser cutter 620 may be moved in the first direction DR1 or the opposite direction to the first direction DR1 by a second cutter driver. The first cutter driver and the second cutter driver may be driven independently of each other.

The laser LB may include the first laser LB1, the second laser LB2, and the third laser LB3. The first laser LB1 may pass through the refractive optical system 400 and may be incident at the first boundary BOU1. The second laser LB2 may bypass the refractive optical system 400 and may be incident at the display area DA and the first boundary BOU1. The third laser LB3 may be blocked by the laser cutter 600 and may not reach the display substrate DS and the carrier substrate CS.

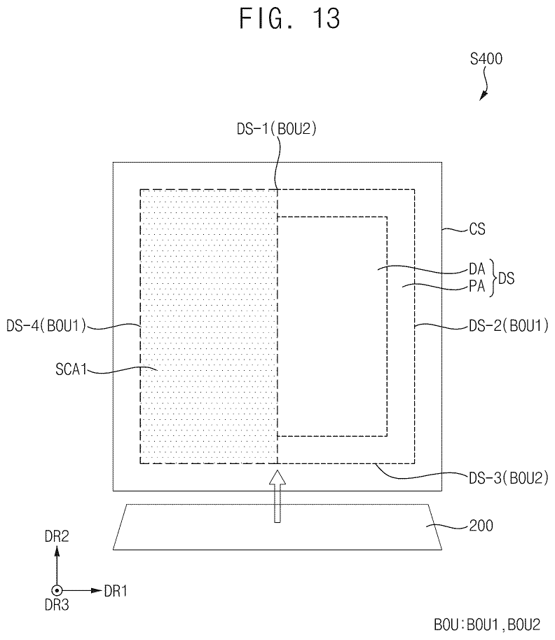

As illustrated in FIGS. 13 and 14, the light source part 200 may move in the second direction DR2 or in the opposite direction to the second direction DR2 and may irradiate the laser LB to the first scan area SCA1. When irradiating the laser LB to the first scan area SCA1, the first refractive optical system 410 and the first laser filter 510 may be positioned on an optical path of the laser LB emitted by the light source part 200. When irradiating the laser LB to the first scan area SCA1, the second refractive optical system 420 and the second laser filter 520 may not be positioned on the optical path of the laser LB emitted by the light source part 200. In other words, the second refractive optical system 420 and the second laser filter 520 may be spaced apart from the optical path of the laser LB. For example, when irradiating the laser LB to the first scan area SCA1, the second laser cutter 620 may move in the opposite direction to the first direction DR1.

The first laser LB1 may pass through the first refractive optical system 410 and the first laser filter 510 and may be incident at the first boundary BOU1 overlapping the first scan area SCA1. The second laser LB2 may bypass the first refractive optical system 410 and the first laser filter 510 and may be incident at the display area DA overlapping the first scan area SCA1 and the first boundary BOU1 overlapping the first scan area SCA1. The first boundary BOU1 overlapping the first scan area SCA1 may correspond to the fourth side DS-4. The third laser LB3 may be blocked by the first laser cutter 610 and the second laser cutter 620 and may not reach the display substrate DS and the carrier substrate CS. For example, the first laser cutter 610 may block the third laser LB3 moving toward a left area of the first scan area SCA1, and the second laser cutter 620 may block the third laser LB3 moving toward a right area of the first scan area SCA1.

Accordingly, the first laser LB1 and the second laser LB2 may be incident at the first boundary BOU1 overlapping the first scan area SCA1. The first laser LB1 and the second laser LB2 may overlap at the first boundary BOU1 overlapping the first scan area SCA1. As a result, a laser having the relatively strong second intensity LB-I2 may be incident at the first boundary BOU1 overlapping the first scan area SCA1.

The second laser LB2 may be incident at the display area DA overlapping the first scan area SCA1, and the first laser LB1 may not be incident at the display area DA overlapping the first scan area SCA1. As a result, a laser having the relatively small first intensity LB-I1 may be incident at the display area DA overlapping the first scan area SCA1.

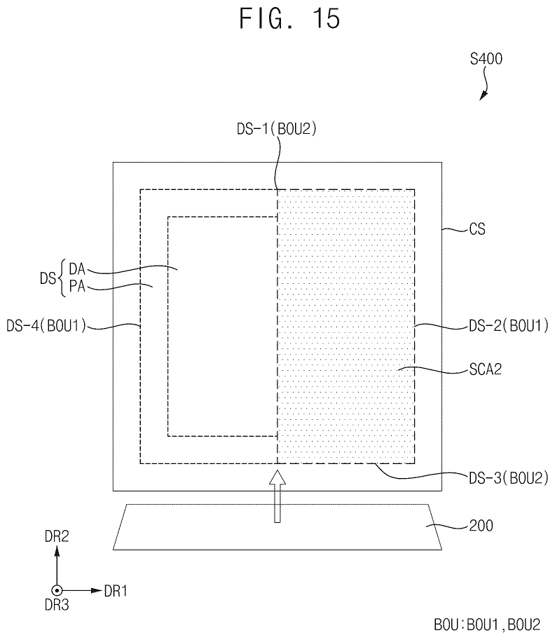

As illustrated in FIGS. 15 and 16, the light source part 200 may move in the second direction DR2 or in the opposite direction to the second direction DR2 and may irradiate the laser LB to the second scan area SCA2. When irradiating the laser LB to the second scan area SCA2, the second refractive optical system 420 and the second laser filter 520 may be positioned on an optical path of the laser LB emitted by the light source part 200. When irradiating the laser LB to the second scan area SCA2, the first refractive optical system 410 and the first laser filter 510 may not be positioned on the optical path of the laser LB emitted by the light source part 200. In other words, the first refractive optical system 410 and the first laser filter 510 may be spaced apart from the optical path of the laser LB. For example, when irradiating the laser LB to the second scan area SCA2, the first laser cutter 610 may move in the first direction DR1.

The first laser LB1 may pass through the second refractive optical system 420 and the second laser filter 520 and may be incident at the first boundary BOU1 overlapping the second scan area SCA2. The second laser LB2 may bypass the second refractive optical system 420 and the second laser filter 520 and may be incident at the display area DA overlapping the second scan area SCA2 and the first boundary BOU1 overlapping the second scan area SCA2. The first boundary BOU1 overlapping the second scan area SCA2 may correspond to the second side DS-2. The third laser LB3 may be blocked by the first laser cutter 610 and the second laser cutter 620 and may not reach the display substrate DS and the carrier substrate CS. For example, the first laser cutter 610 may block the third laser LB3 moving toward a left area of the second scan area SCA2, and the second laser cutter 620 may block the third laser LB3 moving toward a right area of the second scan area SCA2

Accordingly, the first laser LB1 and the second laser LB2 may be incident at the first boundary BOU1 overlapping the second scan area SCA2. The first laser LB1 and the second laser LB2 may overlap at the first boundary BOU1 overlapping the second scan area SCA2. As a result, a laser having the relatively strong second intensity LB-I2 may be incident at the first boundary BOU1 overlapping the second scan area SCA2.

The second laser LB2 may be incident at the display area DA overlapping the second scan area SCA2, and the first laser LB1 may not be incident at the display area DA overlapping the second scan area SCA2. As a result, a laser having the relatively weak first intensity LB-I1 may be incident at the display area DA overlapping the second scan area SCA2.

In conclusion, a laser having the relatively strong second intensity LB-I2 may be incident at the first boundary BOU1 between the display substrate DS and the carrier substrate CS, and a laser having the relatively weak first intensity LB-I1 may be incident at the display area DA of the display substrate DS.

In an embodiment, the second organic layer OL2 may overlap the entirety of the first organic layer OL1 in a plan view. In other words, at least a portion of the second organic layer OL2 may protrude further than the edge of the first organic layer OL1 in a plan view. In this case, the first barrier layer BAL1 may be disposed on the carrier substrate CS. Specifically, the first barrier layer BAL1 may cover the first organic layer OL1 and may contact the carrier substrate CS.

When the first barrier layer BAL1 contacts the carrier substrate CS, if the laser intensity is relatively weak, the laser may be blocked by the first barrier layer BAL1. Accordingly, the laser may not penetrate to the boundary surface BOU between the display substrate DS and the carrier substrate CS. That is, the display substrate DS and the carrier substrate CS may not be sufficiently peeled off.

In an embodiment, the display substrate DS may include a colorless polyimide (“CPI”). For example, the display substrate DS may include a colorless polyimide having a fluorocarbon group (—CF3). In this case, the laser processability may be relatively reduced.

As described above, a laser having the relatively strong second intensity LB-I2 may be incident at the first boundary BOU1 between the display substrate DS and the carrier substrate CS.

Accordingly, even when the first barrier layer BAL1 contacts the carrier substrate CS, the laser can pass through the first barrier layer BAL1 and reach the boundary surface BOU between the display substrate DS and the carrier substrate CS. That is, the display substrate DS and the carrier substrate CS can be effectively peeled off.

In addition, even when the display substrate DS includes a colorless polyimide having the fluorocarbon group, the laser having an intensity capable of peeling the display substrate DS and the carrier substrate CS can reach the boundary surface BOU between the display substrate DS and the carrier substrate CS. That is, the display substrate DS and the carrier substrate CS can be effectively peeled off.

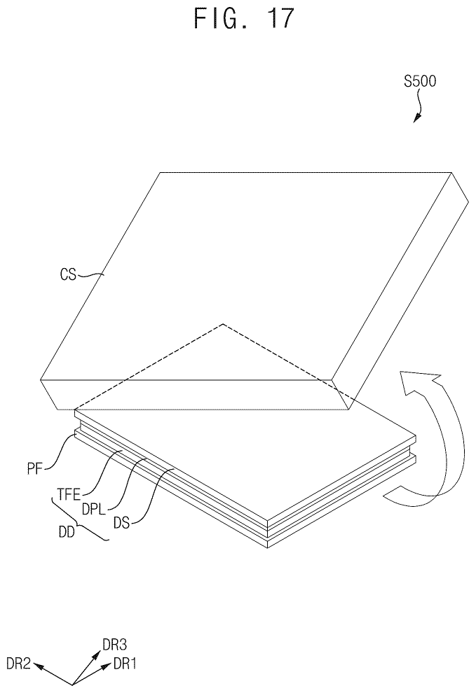

Referring to FIG. 17, after the carrier substrate CS is peeled off, the carrier substrate CS may be removed (S500). Various known methods may be used to remove the carrier substrate CS.

After the carrier substrate CS is removed, the protective film PF formed on the encapsulation layer TFE may be removed. As described above, a laser having the relatively weak first intensity LB-I1 may be incident at the display area DA of the display substrate DS. Accordingly, a defect of the encapsulation layer being peeled off together in the process of removing the protective film PF may be effectively reduced.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A laser processing apparatus, the apparatus comprising:
a stage on which a display substrate having a display area and a carrier substrate are loaded;
a light source part that irradiates a laser to the carrier substrate; and
a refractive optical system that refracts the laser,
wherein the laser includes a first laser that passes through the refractive optical system and a second laser that bypasses the refractive optical system,
wherein the first laser and the second laser are incident at a boundary between the display substrate and the carrier substrate, and
wherein the second laser is incident at the display area of the display substrate.

2. The apparatus of claim 1, wherein a first intensity of the laser incident at the display area of the display substrate is different from a second intensity of the laser incident at the boundary.

3. The apparatus of claim 2, wherein the second intensity is greater than the first intensity.

4. The apparatus of claim 1, further comprising:
a laser filter that passes a portion of the first laser,
wherein the second laser and the portion of the first laser are incident at the boundary.

5. The apparatus of claim 1,
wherein the display substrate includes a first side extending in a first direction and a second side contacting the first side and extending in a second direction intersecting the first direction,
wherein a length of the second side is greater than a length of the first side, and
wherein the boundary corresponds to the second side.

6. The apparatus of claim 5, further comprising:
a transport part that moves the light source part,
wherein the light source part moves in the second direction.

7. The apparatus of claim 1, wherein the laser has a linear shape.

8. The apparatus of claim 1, wherein the laser is an excimer laser.

9. A method of manufacturing a display device, the method comprising:
forming a display substrate having a display area on a first surface of a carrier substrate;
forming a light emitting element in the display area on the display substrate; and
peeling off the display substrate and the carrier substrate by irradiating a laser to the carrier substrate,
wherein a first intensity of the laser incident at the display area of the display substrate is different from a second intensity of the laser incident at a boundary between the display substrate and the carrier substrate.

10. The method of claim 9, wherein the second intensity is greater than the first intensity.

11. The method of claim 9,
wherein the irradiating the laser includes passing the laser through a refractive optical system, and
wherein the laser includes a first laser that passes through the refractive optical system and a second laser that bypasses the refractive optical system.

12. The method of claim 11, wherein the first laser is incident at the boundary.

13. The method of claim 11,
wherein the first laser and the second laser are incident at the boundary, and
wherein the second laser is incident at the display area of the display substrate.

14. The method of claim 11,
wherein the irradiating the laser further includes passing the first laser through a laser filter, and
wherein a portion of the first laser that passes through the laser filter is incident at the boundary.

15. The method of claim 14,
wherein the second laser and the portion of the first laser are incident at the boundary, and
wherein the second laser is incident at the display area of the display substrate.

16. The method of claim 9,
wherein the display substrate includes a first side extending in a first direction and a second side contacting the first side and extending in a second direction intersecting the first direction,
wherein a length of the second side is greater than a length of the first side, and
wherein the boundary corresponds to the second side.

17. The method of claim 16,
wherein the laser has a linear shape, and
wherein the laser scans along the second direction in the irradiating the laser.

18. The method of claim 9, wherein the laser is irradiated to a second surface opposite to the first surface of the carrier substrate.

19. The method of claim 9,
wherein the display substrate includes a first organic layer and a second organic layer disposed on the first organic layer, and
wherein at least a portion of the second organic layer protrudes further than an edge of the first organic layer in a plan view.

20. The method of claim 9, wherein the display substrate includes a colorless polyimide.
